(19) United States
(12) Patent Application Publication
(10) Pub. No.: US 2020/0152496 A1
(43) Pub. Date: May 14, 2020

(54) MICROENVIRONMENT FOR FLEXIBLE SUBSTRATES

(71) Applicant: ENTEGRIS, Inc., Billerica, MA (US)

(72) Inventors: Gary Gallagher, Austin, TX (US); Matthew A. Fuller, Colorado Springs, CO (US); Mark V. Smith, Colorado Springs, CO (US); Barry Gregerson, Excelsior, MN (US); Michael L. Johnson, Minneapolis, MN (US)

(21) Appl. No.: 16/076,082

(22) PCT Filed: Feb. 9, 2017
(86) PCT No.: PCT/US17/17242

§ 371 Date: Aug. 7, 2018

Related U.S. Application Data
(60) Provisional application No. 62/293,240, filed on Feb. 9, 2016.
(60) Provisional application No. 62/294,194, filed on Feb. 11, 2016.

(51) Int. Cl. H01L 21/673

(52) U.S. Cl. CPC H01L 21/67383; H01L 21/67346; H01L 21/67379; H01L 21/67369

(57) ABSTRACT

A substrate container (1100) includes a shell (1105) defining an opening and a door (1505) for selectively sealing the opening. A cantilevered support tray (1120) supports a substrate (1115) within the shell (1105). The support tray (1120) includes a support collar (1300) for coupling the support tray (1120) to a support post (1215) such that the support tray (1120) is cantilevered from the support post (1215).

### CROSS REFERENCE TO RELATED APPLICATIONS

This application claims the benefit of U.S. Provisional Application No. 62/293,240, which was filed on Feb. 9, 2016 and U.S. Provisional Application No. 62/294,194, which was filed on Feb. 11, 2016. The entire content of the applications are incorporated herein by reference.

### TECHNICAL FIELD

The disclosure relates generally to containment of substrates for storage and transport and more specifically to support systems for thin substrates in substrate containers.

### BACKGROUND

Many conventional substrate containers, such as front opening unified pods (FOUPs), are configured to support substrates from their edges. However, as electronics become increasingly compact and miniaturized, there is an emphasis on reducing the thickness of electronic substrates, or providing flexible substrates such as for flexible electronic devices and displays housed within. As a result, substrates have become increasingly thin, to the point that they are not self-supporting when suspended from their edges in a horizontal orientation.

In view of the above, container systems are needed that can support flexible substrates.

### SUMMARY

The present disclosure relates generally to support systems for maintaining flexible substrates in a substantially planar state. Herein, a “substrate” is a structure that is of substantially uniform thickness and, when properly supported, is substantially planar or intended to be substantially planar. Substrate forms include sheets, plates, and slabs. Substrates can be of any shape, including circular, rectangular, and polygonal. Substrates can be of a homogenous or multilayer material, such as glass, silicon, glass epoxy, or films. Substrates can also include a composition of materials, such as doped materials (e.g., glass epoxy doped with copper or carbon), laminated or coated composites, or core materials with coatings deposited thereon. Non-limiting examples of substrates include reticles used in lithography applications and silicon wafers that have been processed or partially processed by lithography techniques. Herein, a “flexible substrate” is a substrate that when supported by its periphery or individual points is unable maintain a substantially planar condition without applied tension.

Various embodiments relate to the transport, storage, and handling of flexible substrates of varying thickness using a FOUP, for example a 300 mm or 450 mm FOUP. Some embodiments also relate to transferring the flexible substrates into and out of the FOUP between varying processes or process equipment.

In one illustrative embodiment, a substrate container comprises a shell defining an opening and a door configured to selectively seal the opening. A cantilevered support tray is configured to support a substrate within the shell. Preferably, the support tray is cantilevered from at least one support post. In certain embodiments, the cantilevered support tray may include a support collar configured to couple the support tray to a support post. The support collar can encircle the support post.

In one embodiment, the cantilevered support tray includes a registration ledge configured to contact a rearward edge of a substrate supported by the support tray. The support tray further includes a tab feature extending forward from the registration ledge, the tab feature being configured to limit side-to-side movement of a substrate supported by the support tray.

The cantilevered support tray can include a pin extending upward from the support tray, the pin being configured to mate with a registration hole of a substrate supported by the cantilevered support tray. In a preferred embodiment, the pin has a tapered profile near a distal end of the pin.

A retention mechanism can be coupled to the door. In one embodiment, the retention mechanism can be configured to prevent movement of a substrate by means of clamping it to the cantilevered support tray in a first direction. Preferably, the retention mechanism is further configured to prevent movement of a substrate supported by the support frame in at least one of second direction or different direction.

In another embodiment, a substrate container comprises a shell defining an opening, a door configured to selectively seal the opening and a support frame. The support frame includes a frame configured to support a substrate and a latch assembly coupled to the frame. The frame defines an inner perimeter and an outer perimeter. The latch assembly is configured to selectively engage a substrate, and in certain embodiments a flexible substrate, supported by the frame at a location between the inner perimeter and the outer perimeter.

In certain embodiments, the frame may further includes a spring member in contact with the latch assembly. The spring member is configured to bias the latch assembly into a latched configuration and into a fully open configuration. In one aspect, the latch assembly includes a cam lobe in contact with the spring member. Preferably, the spring member is cantilevered from and formed integrally with the frame.

The latch assembly may include a hinge pin and a latch arm configured to pivot about the hinge pin. Preferably, the latch arm includes a rib configured to selectively engage a substrate supported by the frame.

In one embodiment, the frame includes an inset corner configured to provide access to a corner of a substrate supported by the frame from outside the frame.

The preceding summary is provided to facilitate an understanding of some of the innovative features unique to the present disclosure and is not intended to be a full description. A full appreciation of the disclosure can be gained by taking the entire specification, claims, drawings, and abstract as a whole.

### BRIEF DESCRIPTION OF THE DRAWINGS

The disclosure may be more completely understood in consideration of the following description of various illustrative embodiments in connection with the accompanying drawings, in which:

FIG. 1 is a perspective view of a substrate container with support trays in accordance with an embodiment of the present invention with its door removed.

FIG. 2 is a partial sectional view of the substrate container of FIG. 1.

FIG. 3 is a partial sectional view of the substrate container of FIG. 1.

FIG. 4 is a side sectional view of the substrate container of FIG. 1.

FIG. 5 is a side sectional view of the substrate container of FIG. 1.

FIG. 6 is a perspective view of the substrate container of FIG. 1 with its shell removed to show the inner structure.

FIG. 7 is a perspective view of the substrate container of FIG. 1 with its shell removed to show the inner structure.

FIG. 8 is a perspective view of a cantilevered support tray in accordance with an embodiment of the present invention.

FIG. 9 is a perspective view of a cantilevered support tray in accordance with an embodiment of the present invention.

FIG. 10 is a side sectional view of a substrate container in accordance with an embodiment of the present invention.

FIG. 11 is a perspective view of a support tray including pins in accordance with an embodiment of the present invention.

FIG. 12 is an enlarged view of a portion of FIG. 11.

FIG. 13 is a side view of a pin of the support tray of FIG. 11.

FIG. 14 is a perspective view of a substrate supported on the support tray of FIG. 11.

FIG. 15 is an enlarged view of a portion of FIG. 14.

FIGS. 16A and 16B show a cantilevered support tray in accordance with an embodiment of the present invention.

FIG. 17 is a partial side view of a door-based retainer in accordance with an embodiment of the present invention.

FIGS. 18A and 18B show an open substrate container in accordance with an embodiment of the present invention.

FIG. 19 shows a thin substrate supported by a frame in accordance with an embodiment of the present invention.

FIGS. 20A and 20B show the frame of FIG. 19 in partial assembly.

FIG. 21 is a schematic view of a latch assembly interacting with a cantilever spring in accordance with an embodiment of the present invention.

FIG. 22 is a schematic view of the latch assembly and cantilever spring of FIG. 21.

FIG. 23 is a schematic view of the latch assembly and cantilever spring of FIG. 21.

FIGS. 24A and 24B show the thin substrate and frame of FIG. 19 in partial assembly.

FIGS. 25A-C show a thin substrate supported by a frame having inset corners in accordance with an embodiment of the present invention.

FIGS. 26A and 26B show the thin substrate and frame of FIGS. 25A-C in partial assembly.

FIG. 27 shows a thin substrate supported by a frame with elongate latches in accordance with an embodiment of the present invention.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The terms “preferred” and “preferably” refer to embodiments of the invention that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the invention.

The following detailed description should be read with reference to the drawings in which similar elements in different drawings are numbered the same. The detailed description and the drawings, which are not necessarily to scale, depict illustrative embodiments and are not intended to limit the scope of the disclosure. The illustrative embodiments depicted are intended only as exemplary. Selected features of any illustrative embodiment may be incorporated into an additional embodiment unless clearly stated to the contrary.

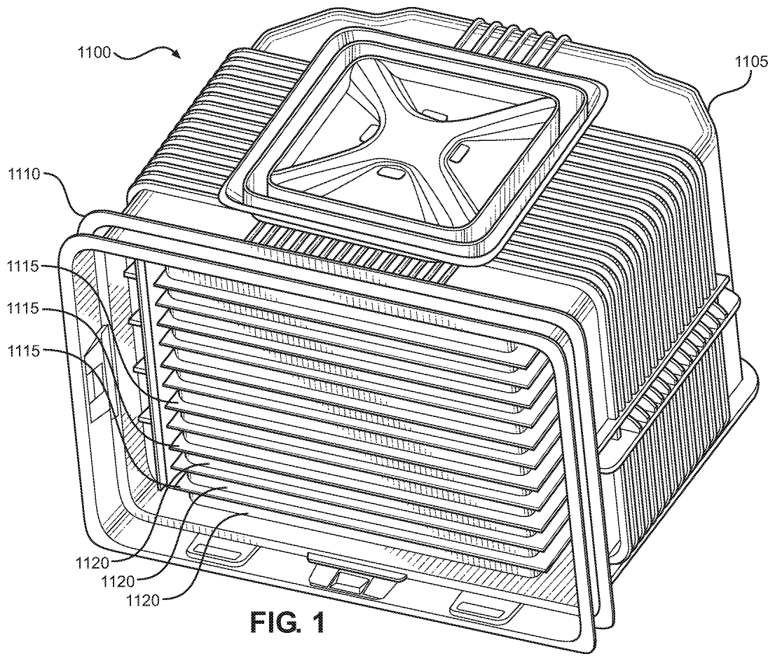

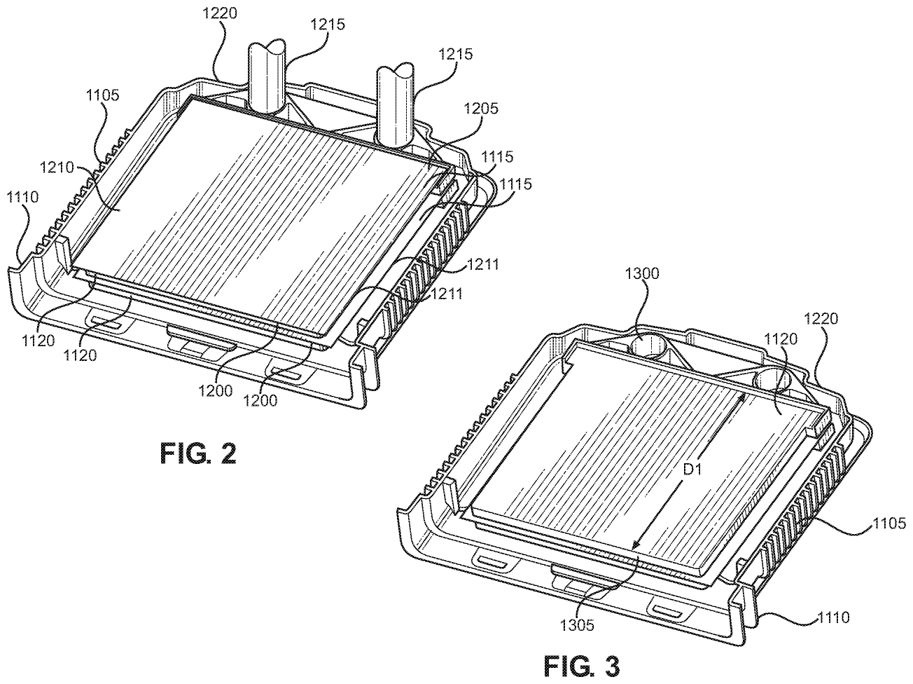

Referring to FIGS. 1-3, a front opening unified pod (FOUP) 1100 is depicted in accordance with an embodiment of this disclosure. FOUP 1100 includes a shell portion 1105 defining a door frame 1110. Housed within shell portion 1105 are a plurality of thin substrates 1115, each disposed on a respective support tray 1120. Thin substrates 1115 are characterized as having forward edges 1200, rearward edges 1205, and opposing lateral edges 1210, 1211 that extend between forward edges 1200 and rearward edges 1205, as shown in FIG. 2.

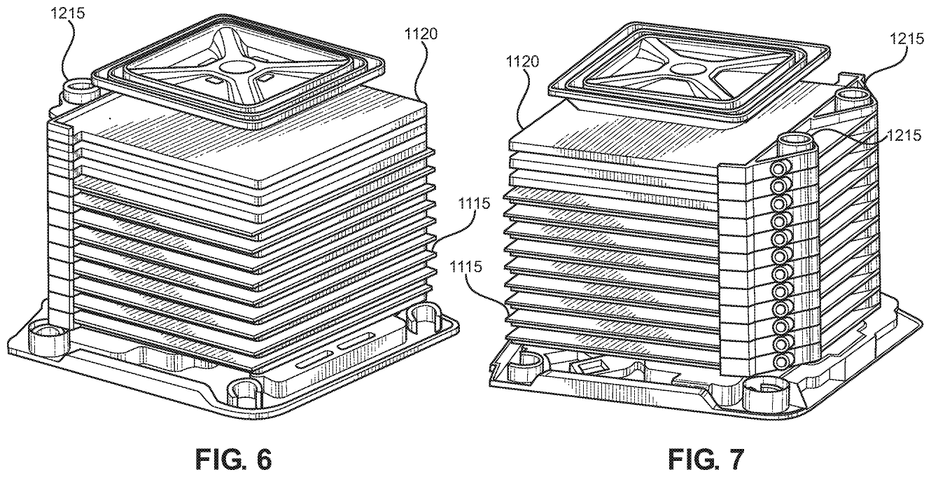

Support trays 1120 include support collars 1300 defined at the rearward ends thereof, as shown in FIG. 3. Support trays 1120 are cantilevered from support posts 1215, which pass through support collars 1300, as shown in FIG. 2. Support posts 1215 are disposed proximate a rear wall 1220 of shell portion 1105. Support trays 1120 are undersized relative to the width of resident thin substrates 1115. In various embodiments, support trays 1120 are fabricated from a low density, high modulus material. Support trays 1120 can include a cushion material, such as a soft foam, mounted to a registration surface. FIGS. 6 and 7 show FOUP 1100 without shell portion 1105.

Functionally, support trays 1120 are suitable for supporting thin substrates 1115, to allow for accurate automated loading and unloading of the flexible substrates. The undersized width of support trays 1120 relative to resident thin substrates 1115 enables automation edge gripping access. Materials of low density and/or high modulus militate against sagging of support trays 1120.

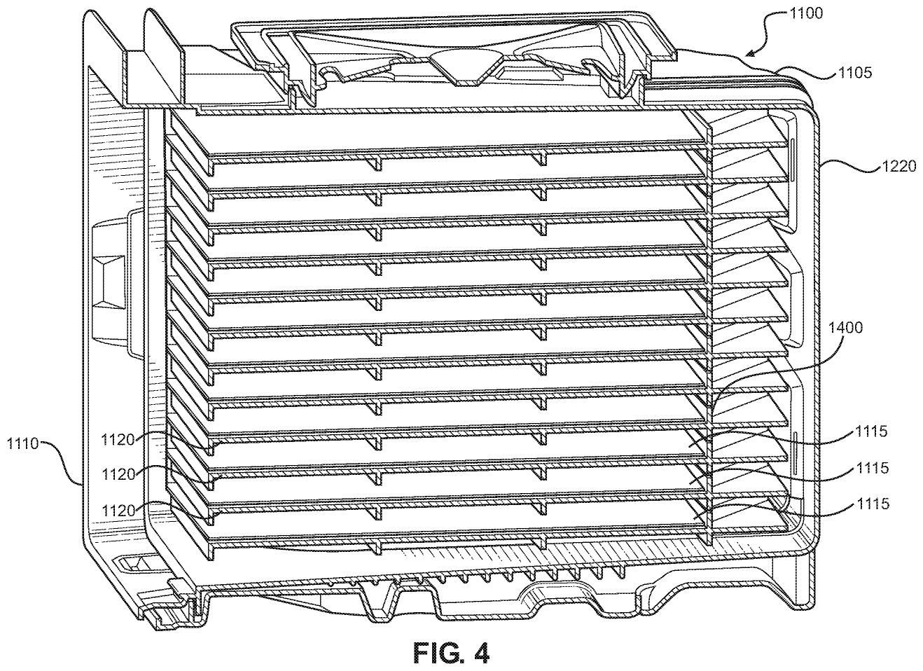

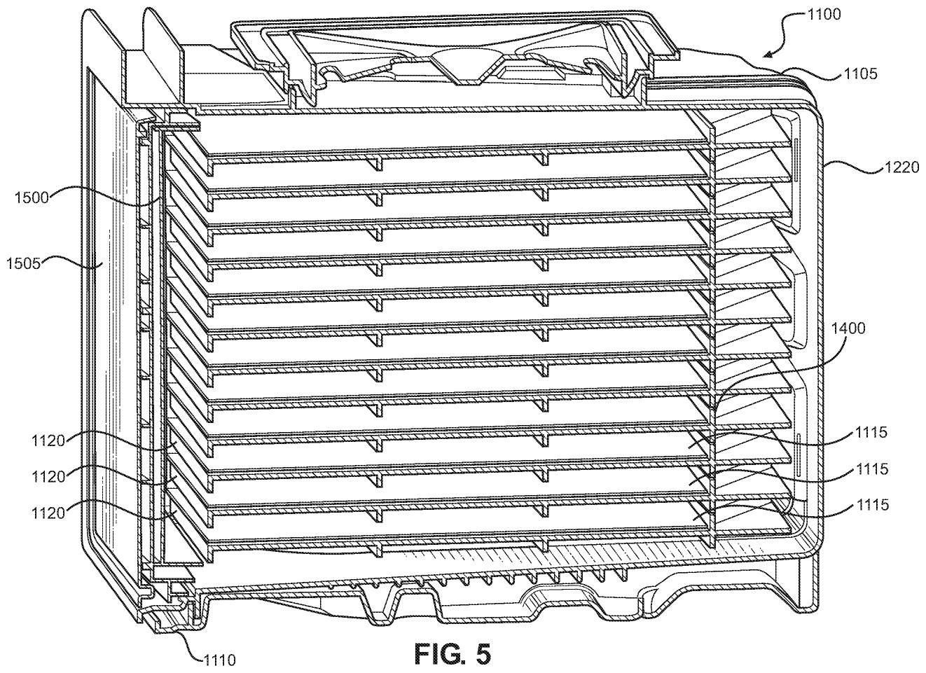

Referring to FIGS. 4 and 5, sectional views of FOUP 1100 are presented. Each support tray 1120 may include a registration ledge 1400 proximate the rearward end. With reference to FIG. 3, a minimum dimension D1 is defined in the z-direction between a front of registration ledge 1400 and a front edge 1305 of support tray 1120. In one embodiment, minimum dimension D1 is sized to be substantially equal to the length of thin substrate 1115 in the z-dimension. Returning to FIG. 5, a door cushion 1500 is shown mounted to a door 1505. Door cushion 1500 is adapted to pinch forward edges 1200 of thin substrates 1115 to their respective support trays 1120 upon engagement within door frame 1110. Door 1505, cushion 1500 or both can also be configured to interlock with front edge 1305 of support trays 1120.

Functionally, matching the z-dimension of thin substrate 1115 with dimension D1 of support tray 1120 enables thin substrate 1115 to be positioned flush with the front of support tray 1120 by registering rearward edge 1205 of thin substrate 1115 to registration ledge 1400 of support tray 1120. The pinching of forward edge 1200 of thin substrate 1115 to the front of support tray 1120 captures thin substrate 1115 onto support tray 1120 during shipping and handling. The interlocking of support trays 1120 to cushion 1500 or door 1505 increases the stability of the array of support trays 1120 during handling and transport of FOUP 1100.

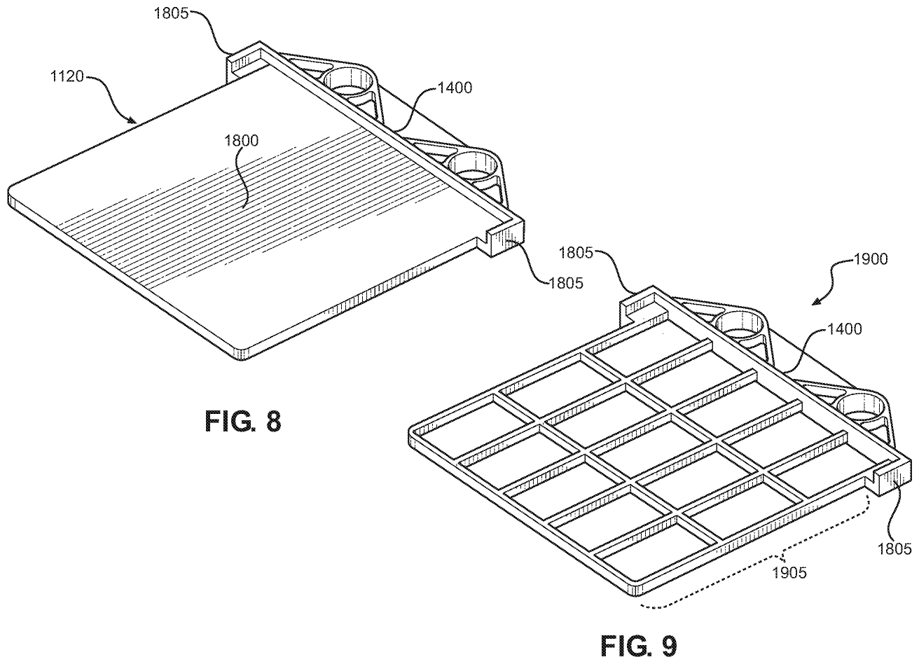

Referring to FIGS. 8 and 9, support trays are presented in isolation in accordance with embodiments of this disclosure. In FIG. 8, support tray 1120 includes a substantially flat, continuous surface 1800. In FIG. 9, a support tray 1900 defines an open grid or lattice structure 1905. In some embodiments, support trays 1120, 1900 include tab features 1805 that extend forward from the ends of registration ledges 1400 to limit side-to-side movement of a resident thin substrate. Tab features 1805 provides a locating feature for the substrate and can also provide stiffening to trays 1120, 1900 to limit the unsupported length of the cantilevered arrangement.

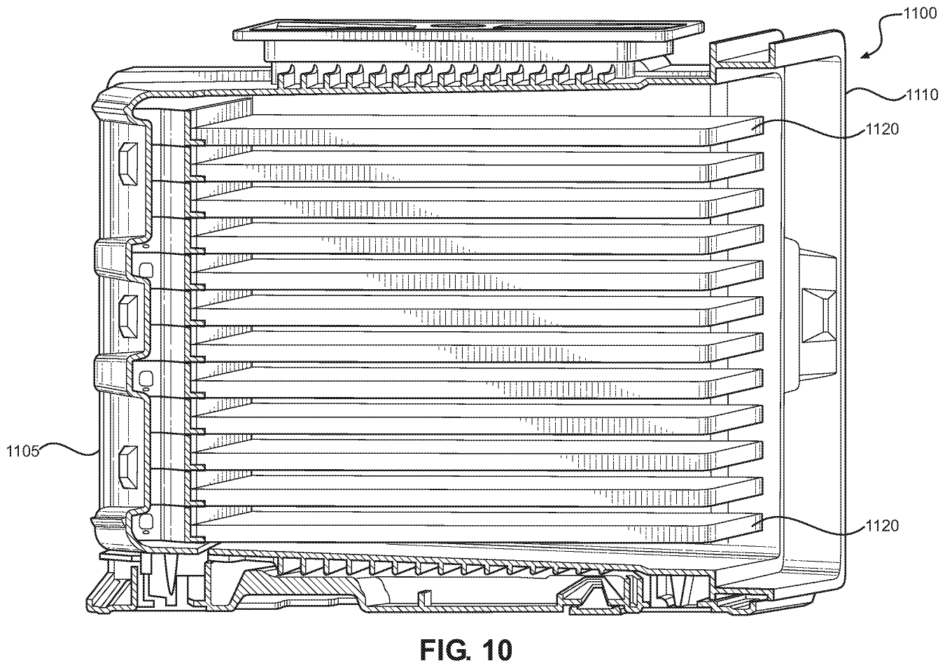

Referring to FIG. 10, a sectional view of FOUP 1100 is provided showing example clearances between shell portion 1105 and the lowermost and uppermost support trays 1120. Those of ordinary skill in the art will recognize that specific clearance dimensions are a design choice dependent upon various factors, including, but no limited to, the specific substrate, the tray dimensions, and end use processes and applications.

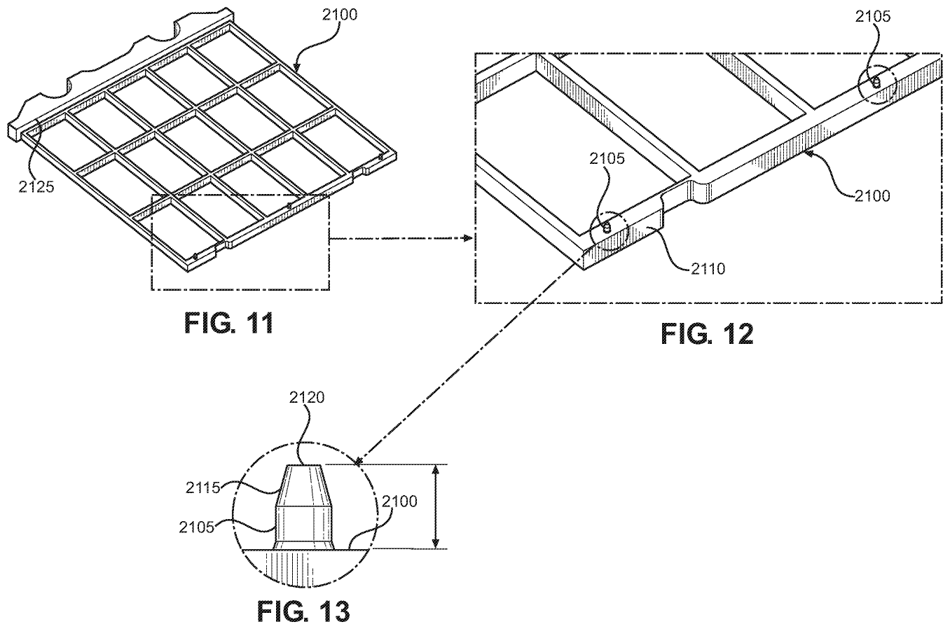

Referring to FIGS. 11-13, a modified support tray 2100 is depicted in accordance with an embodiment of this disclosure. Modified support tray 2100 includes a plurality of pins 2105 proximate a front edge 2110 of tray 2100, pins 2105 extending upward from tray 2100. Pins 2105 are generally cylindrical, with a tapered or frusto-conical profile 2115 near a distal end 2120. In some embodiments, additional pins (not depicted) are disposed proximate a registration ledge 2125 of modified support tray 2100. Pins 2105 can be integrally formed with modified support tray 2100 or, alternatively, formed separately from and press fit into modified support tray 2100.

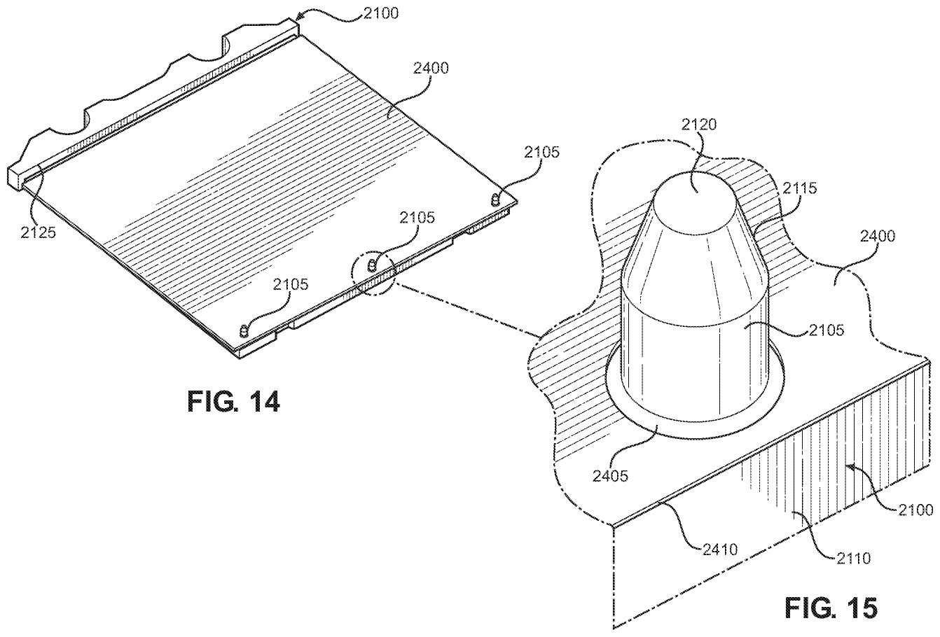

Referring to FIGS. 14 and 15, modified support tray 2100 is shown supporting a modified thin substrate 2400. Thin substrate 2400 includes registration holes 2405 located within a predetermined area proximate an edge 2410 of thin substrate 2400. Registration holes 2405 are spaced in accordance with the spacing of pins 2105 of modified support tray 2100, both relative to each other and relative to the distance from registration ledge 2125.

In operation, the rearward edge of thin substrate 2400 is registered against registration ledge 2125, and the forward edge is lowered so that registration holes 2405 of thin substrate 2400 pass over pins 2105. Frusto-conical profiles 2115 help align thin substrate 2400 so that registration holes 2405 are centered as thin substrate 2400 is lowered into contact with the upper face of modified support tray 2100.

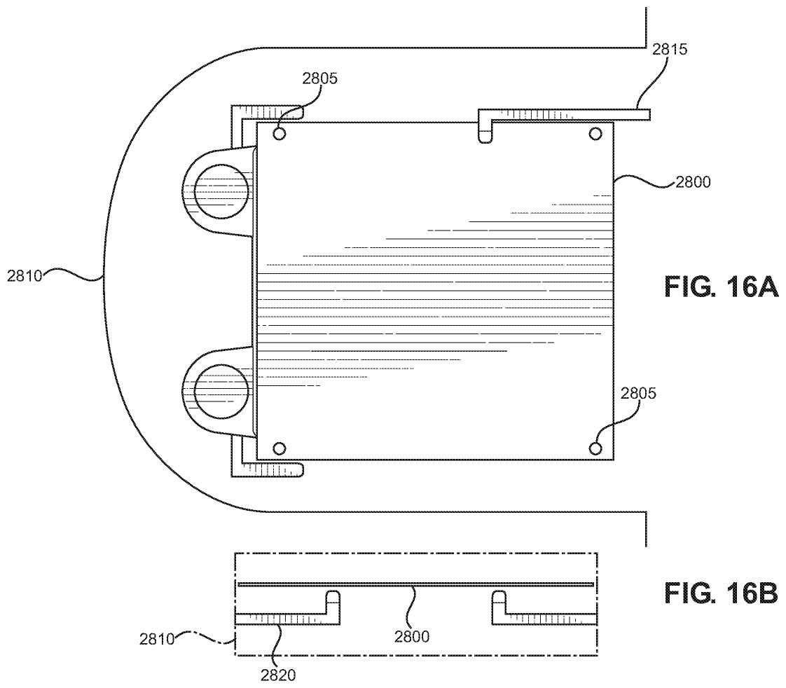

Referring to FIGS. 16A and 16B, a cantilevered support tray 2800 is depicted schematically in accordance with an embodiment of this disclosure. Support tray 2800 includes a plurality of pins 2805, with two pins 2805 located proximate a front of support tray 2800 and two pins 2805 located proximate a rear of support tray 2800. Pins 2805 function in the same manner as pins 2105. In addition, a FOUP 2810 is illustrated as having a retention mechanism 2815, which is actuated by a door of FOUP 2810 (not depicted). When actuated, retention mechanism 2815 contacts a substrate supported on support tray 2800 (not depicted) to retain the substrate on support tray 2800. FIG. 16B shows optional front supports 2820, which can be used to provide additional stability to support tray 2800.

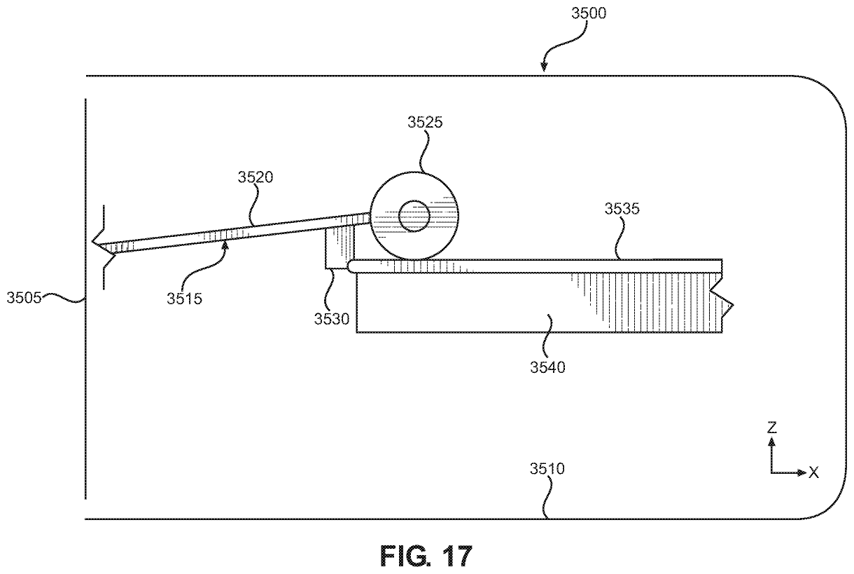

The embodiment of FIG. 17 depicts a door retention system. Specifically, a FOUP 3500 includes a door 3505 and a shell 3510. A retention mechanism 3515 is coupled to door 3505. Retention mechanism 3515 includes a spring 3520, a roller 3525 and a downwardly extending projection 3530. A substrate 3535 is shown supported on a cantilevered support tray 3540. Spring 3520 and roller 3525 retain substrate 3535 in the z-direction, while projection 3530 retains substrate 3535 in the x-direction.

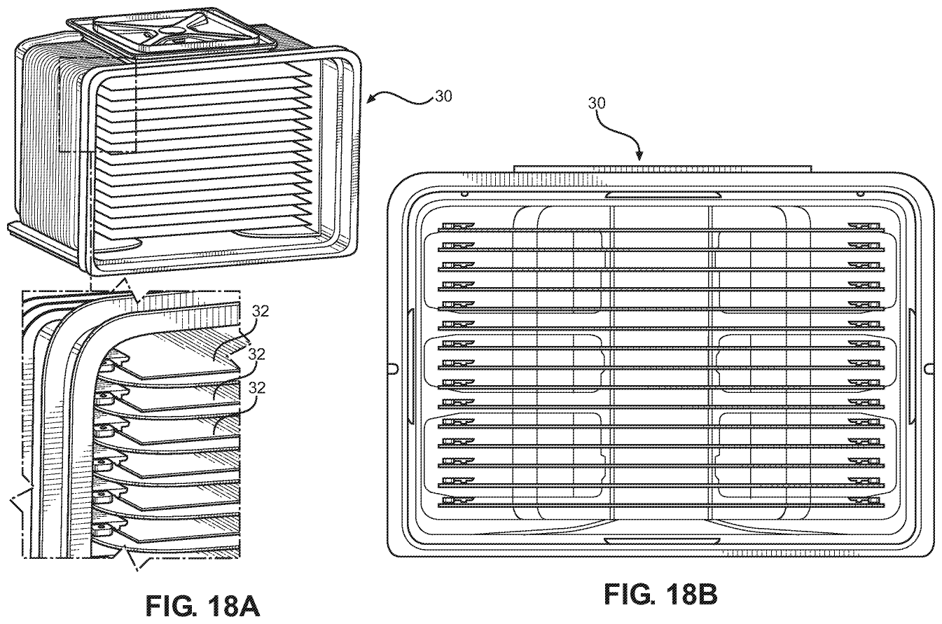

Referring to FIGS. 18A and 18B, an open substrate container 30, housing a plurality of framed thin substrates 32, is depicted in accordance with an embodiment of this disclosure. Framed thin substrates 32 can be supported at their edges by shelves (not depicted) such as found in conventional front opening unified pods (FOUPs). To show the interior of substrate container 30, substrate container 30 is presented without a door. In the depicted embodiment, substrate container 30 is capable of accommodating fifteen framed thin substrates 32.

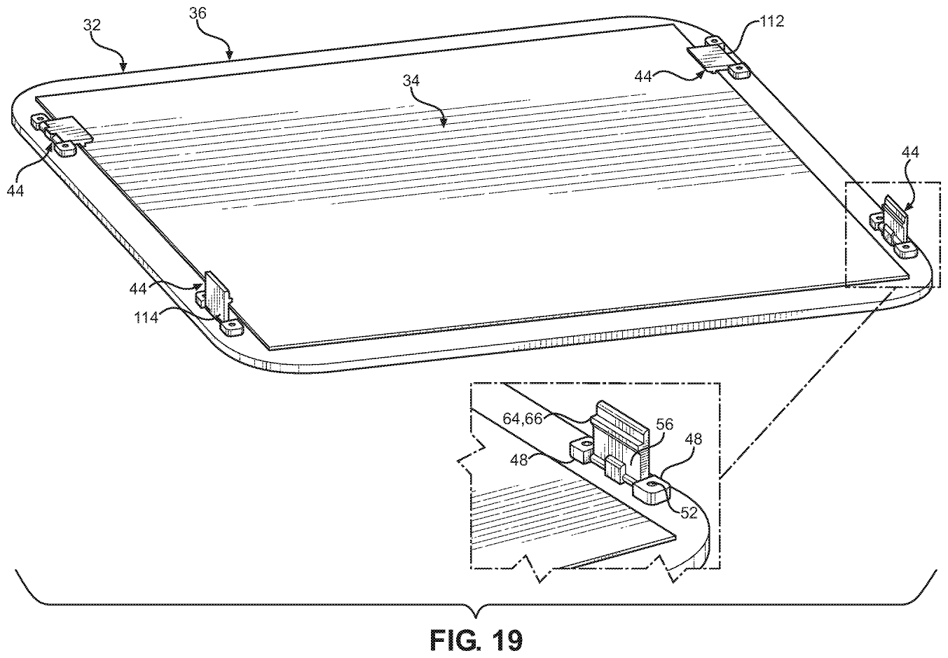

An alternative approach for supporting flexible substrates includes a frame and latch assembly that can either be attached to or supported by the cantilevered supports of this disclosure or by a conventional guides or slots in a substrate container. Referring to the embodiment of FIGS. 19-24, framed flexible substrate 32 includes a flexible substrate 34 and a frame assembly 36. Frame assembly 36 includes a frame 42 and a plurality of latch assemblies 44. In the depicted embodiment, latch assemblies 44 are disposed on opposing sides and proximate the corners of frame 42.

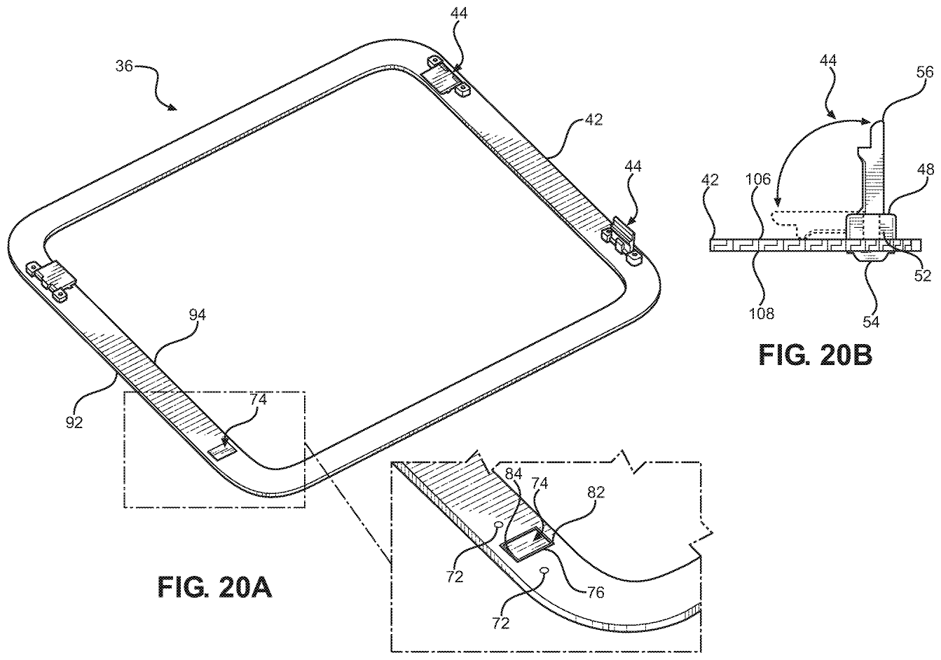

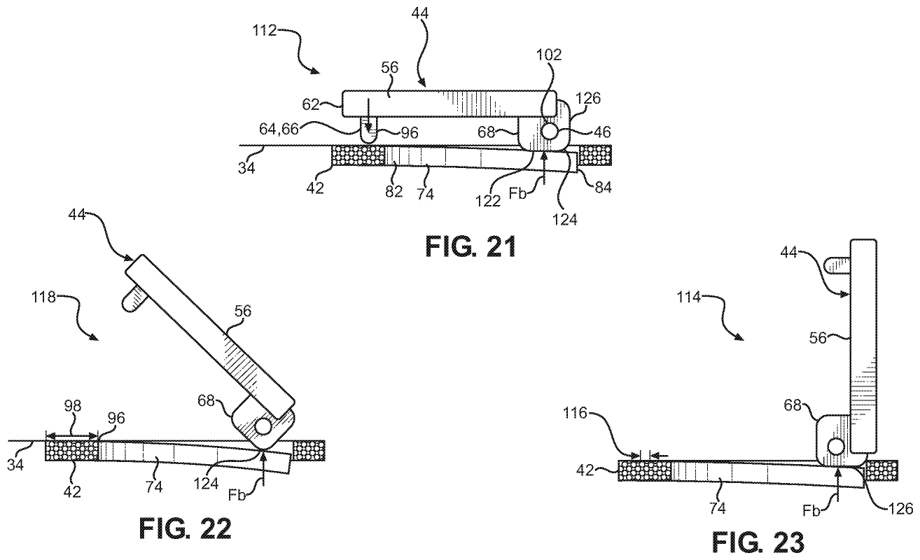

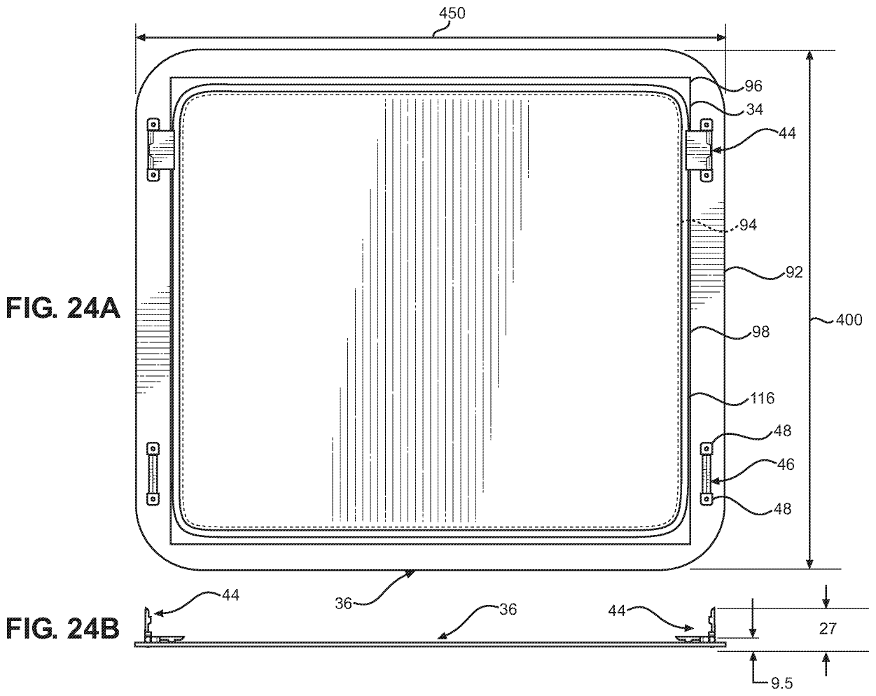

In certain embodiments, each latch assembly 44 may include a hinge pin 46 supported on opposing ends by posts 48, as best seen in FIG. 24A. Posts 48 can include threaded bores 52 for engaging fasteners 54, as best seen in FIGS. 19 and 20B. A latch arm 56 pivots about hinge pin 46. Latch arm 56 includes a proximal end portion 58 that pivots about hinge pin 46 and a distal end portion 62 that defines a hold down feature 64, as best seen in FIGS. 21-23. In the depicted embodiment, hold down feature 64 is a rib 66 that extends parallel to hinge pin 46. Proximal end portion 58 of latch arm 56 includes a cam lobe 68. Cam lobe 68 and hold down feature 64 extend from the same side of latch arm 56.

Latch assemblies 44 may be affixed or mounted to frame 42. Frame 42 defines through-holes 72 through which fasteners 54 pass to fasten posts 48 to frame 42, as best seen in FIG. 20A. Frame 42 includes a cantilever spring portion 74, as best seen in FIGS. 20-23. Preferably, cantilever spring 74 is integral to frame 42, defined by a through-slot 76 that outlines cantilever spring 74. Cantilever spring 74 includes a fixed end 82 and a free end 84, free end 84 being disposed proximate hinge pin 46. Alternatively, a mechanical spring (not depicted) that is non-integral can be used.

As best seen in the embodiment of FIG. 24A, frame 42 defines an outer perimeter 92 and an inner perimeter 94 and is sized so that an edge portion 96 of thin substrate 34 overlaps inner perimeter 94 to contact a predesignated overlap zone 98 of frame 42 proximate outer perimeter 92.

In various embodiments, frame 42 is made of a high modulus material (i.e., a material having a modulus of elasticity greater than 65 gigapascals (GPa)). In some embodiments, frame 42 is made of a carbon fiber composite, such as carbon fiber-filled epoxy. Latch assemblies 44 can be made of a metal, such as aluminum or stainless steel.

In assembly, hinge pin 46 is inserted through a lateral bore 102 (best seen in FIG. 21) that extends laterally through proximal end portion 58 of latch arm 56. Hinge pin 46 and lateral bore 102 define a clearance fit that enables latch arm 56 to rotate about hinge pin 46. Alternatively, hinge pin 46 can be press fit or otherwise formed to extend laterally from the sides of latch arm 56 and configured to rotate within posts 48. Latch arm 56 is mounted to frame 42 so that hold down feature 64 faces or is in contact with frame 42. As best seen in FIGS. 20A and 20B, threaded bores 52 of posts 48 are aligned over through-holes 72 on a top side 106 of frame 42. Fasteners 54 are fed through through-holes 72 from a bottom side 108 of frame 42 and threaded into threaded bores 52 of posts 48 to secure latch assembly 44 to frame 42. This process is repeated for each of the plurality of latch assemblies 44.

Functionally, latch arm 56 can be selectively placed in a latched configuration 112 (shown in FIG. 21) or a fully open configuration 114 (shown in FIG. 23). In latched configuration 112, latch arm 56 is rotated toward frame 42 so that hold down feature 64 makes contact with frame 42 or a resident thin substrate 34. An area or zone within which hold down feature 64 makes contact with frame 42, or over which thin substrate 34 makes contact with hold down feature 64, is herein referred to as a contact band 116 of frame 42 (shown in FIGS. 23 and 24). Contact band 116 falls within overlap zone 98 of frame 42. In fully open configuration 114, latch arm 56 is rotated away from frame 42. Also, in fully open configuration 114, latch arm 56 can sufficiently clear overlap zone 98 of frame 42 to enable thin substrate 34 to be lowered onto frame 42 without excessive bending or incidental collisions with latch assembly 44.

As shown in FIGS. 21-23, cam lobe 68 is engaged with cantilever spring 74 proximate free end 84 to exert a biasing force Fb against latch arm 56. In latched configuration 112 of FIG. 21, free end 84 exerts biasing force Fb against a first flat or dwell portion 122 of cam lobe 68, which maintains latch assembly 44 in latched configuration 112 and causes hold down feature 64 to engage frame 42 or resident thin substrate 34 with a downward retention force Fr. Upon opening of latch assembly 44, as shown in FIG. 22, latch assembly 44 enters an intermediate configuration 118 wherein a rounded or rise portion 124 of cam lobe 68 engages cantilever spring 74. When engaged, rise portion 124 further deflects free end 84 of cantilever spring 74 and increases biasing force Fb exerted against cam lobe 68. As rise portion 124 of cam lobe 68 passes over cantilever spring 74, latch assembly 44 enters into fully open configuration 114, which is shown in FIG. 23. In fully open configuration 114, a second flat or dwell portion 126 of cam lobe 68 engages cantilever spring 74. Free end 84 of cantilever spring 74 exerts biasing force Fb against second dwell portion 126 of cam lobe 68, which maintains latch assembly 44 in fully open configuration 114.

Biasing force Fb exerted by cantilever spring 74 against cam lobe 68 is greater when rise portion 124 is engaged than when first or second dwell portion 122, 126 is engaged. This dynamic forces latch assembly 44 off center when in intermediate configuration 118. Accordingly, latch assemblies 44 are predisposed to remain in either latched configuration 112 or fully open configuration 114. Also, the higher force required to enter intermediate configuration 118 from either latched configuration 112 or fully open configuration 114 deters latch assembly 44 from spuriously entering intermediate configuration 118. Only by imposition of an external influence on latch arm 56, such as the action of a robot or operating personnel, does latch assembly 44 enter into intermediate configuration 118.

In operation, thin substrate 34 is registered on frame 42 so that edge portion 96 of thin substrate 34 is aligned over overlap zone 98 of frame 42. In some embodiments, latch assemblies 44 are in fully open configuration 114 during registration of thin substrate 34. Latch arms 56 of latch assemblies 44 are then rotated to place latch assemblies 44 into latched configuration 112, with hold down features 64 engaging edge portion 96 of thin substrate 34 and pinching thin substrate 34 between hold down features 64 and contact bands 116 of frame 42. In this way, thin substrate 34 is secured to frame assembly 36. To release thin substrate 34 from frame assembly 36, latch assemblies 44 are opened, and thin substrate is removed 34. In some embodiments, latch assemblies 44 are in fully open configuration 114 during removal of thin substrate 34.

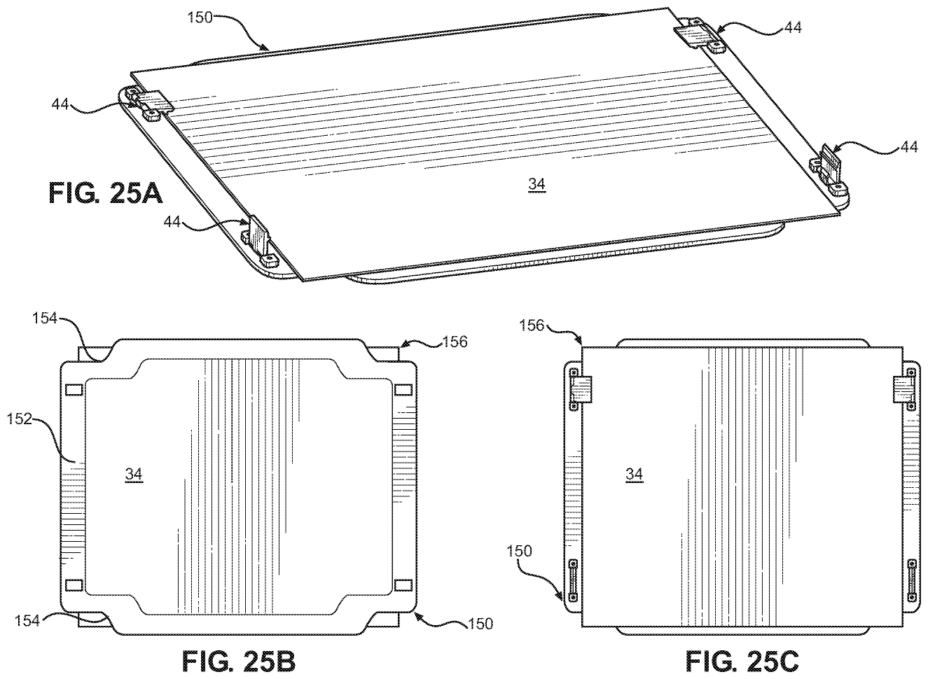

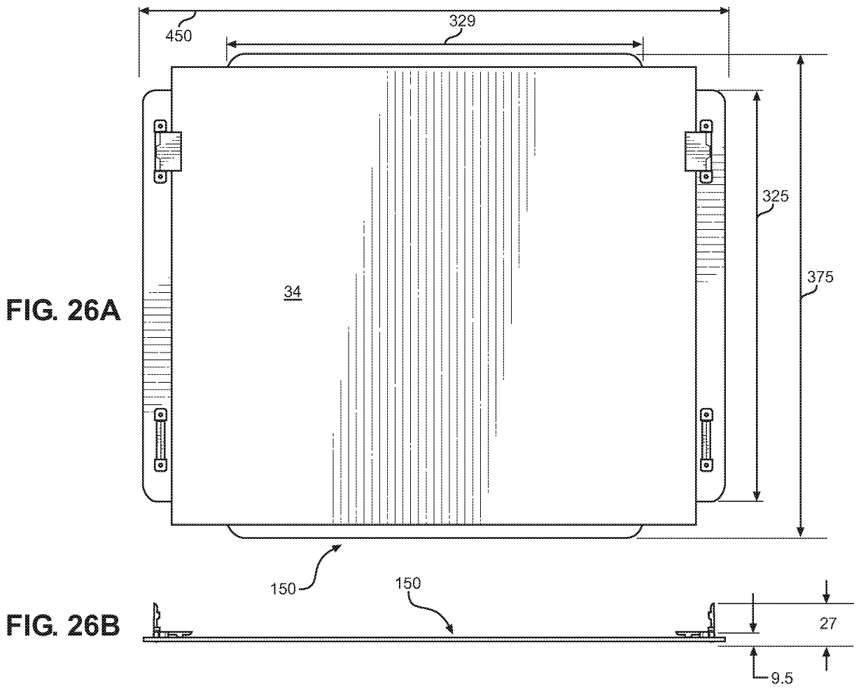

The embodiment of FIGS. 25A-C, 26A and 26B depict a modified frame assembly 150. Modified frame assembly 150 includes some of the same components and attributes as frame assembly 36 of FIGS. 18-24, with these components identified by the same reference numerals. Modified frame assembly 150 is distinguished by a modified frame 152 that includes inset corners 154. Inset corners 154 provide access to corners 156 of resident thin substrate 34 from outside modified frame assembly 150 for purposes of gripping and handling.

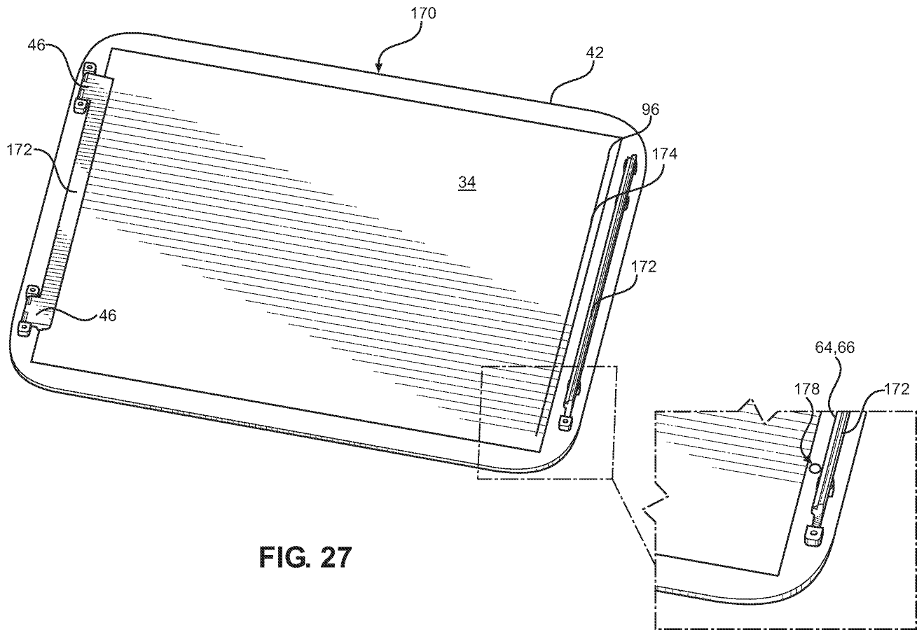

Referring to FIG. 27, a frame assembly 170 having laterally elongated latch assemblies 172 is depicted in accordance with an embodiment of this disclosure. Frame assembly 170 includes some of the same components and attributes as frame assembly 36 of FIGS. 18-24, with these components identified by the same reference numerals. Each laterally elongated latch assembly 172 includes a laterally elongated latch arm 176 that bridges between two hinge pins 46 on a common side of frame 42. Laterally elongated latch assembly 172 provides for a longer line of contact 174 along edge portion 96 of resident thin substrate 34. Line of contact 174 can be provided by a single rib 66 or by a plurality of ribs 66, or other hold down features 64, spaced along laterally elongated latch arm 176.

Also depicted in the embodiment of FIG. 27 is an access hole 178 that passes through frame 42 proximate distal end portion 62 of laterally elongated latch arm 176 but outside overlap zone 98 of resident thin substrate 34. Access hole 178 enables opening of laterally elongated latch assembly 172 by passing a pin (not depicted) through access hole 178 to actuate laterally elongated latch arm 176. While access hole 178 is depicted in association with laterally elongated latch assembly 172 of FIG. 27, it should be understood that such access holes can be utilized with any of the latch assemblies and frame assemblies depicted or described herein.

The following patents and patent application publications, commonly assigned to the owner of the present disclosure, are incorporated herein by reference in their entireties except for the claims and express definitions contained therein: U.S. Pat. Nos. 7,100,772, 7,316,325, 7,347,329, 7,886,910 and 8,276,759; U.S. Patent Application Publication Nos. 2009/0194456, 2013/0270152, 2013/0319907, 2014/0319020 and 2015/0083640; International Application Publication No. WO 2013/025629 A3.

While the foregoing discussion and attendant figures are directed primarily to thin substrates, the present invention is not limited to the support or storage of thin substrates. The storage and transport of other substrates, such as but not limited to flat displays and flexible electronics, is also contemplated. It is further noted that various figures include dimensions. The dimensions are representative of certain embodiments and are not to be construed as limiting.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respect, only illustrative. Changes may be made in details, particularly in matters of shape, size, and arrangement of parts without exceeding the scope of the disclosure. The disclosure's scope is, of course, defined in the language in which the appended claims are expressed.

What is claimed is:

1. A substrate container comprising:
a shell defining an opening;
a door configured to selectively seal the opening; and
a cantilevered support tray configured to support a flexible substrate within the shell.

2. The substrate container of claim 1, further comprising a support post, wherein the support tray is cantilevered from at least one support post.

3. The substrate container of claim 2, further comprising at least one support collar configured to couple the support tray to the at least one support post.

4. The substrate container of claim 3, wherein the at least one support collar surrounds the at least one support post.

5. The substrate container of claim 1, wherein the support tray comprises a registration ledge configured to contact a rearward edge of a substrate supported by the support tray.

6. The substrate container of claim 5, wherein the support tray further comprises a tab feature extending forward from the registration ledge, the tab feature being configured to limit side-to-side movement of a substrate supported by the support tray.

7. The substrate container of claim 1, wherein the support tray comprises a pin extending upward from the support tray, the pin being configured to mate with a registration hole of a substrate supported by the support tray.

8. The substrate container of claim 7, wherein the pin has a tapered profile near a distal end of the pin. The substrate container of claim 1, further comprising a retention mechanism coupled to the door, the retention mechanism being configured to prevent movement of a substrate supported by the support tray in a first direction.

9. The substrate container of claim 1, further comprising a retention mechanism coupled to the door, the retention mechanism being configured to prevent movement of a substrate supported by the support tray in a first direction.

10. The substrate container of claim 9, wherein the retention mechanism is further configured to prevent movement of a substrate supported by the support frame in a second direction, the second direction being perpendicular to the first direction.

11. A support tray configured to support a substrate within a substrate container, the support tray comprising:
At least one support collar configured to couple the support tray to at least one support post such that the support tray is cantilevered from the at least one support post.

12. The support tray of claim 11, wherein the at least one support collar is configured to surround the at least one support post.

13. The support tray of claim 11, wherein the support tray comprises a registration ledge configured to contact a rearward edge of a substrate supported by the support tray.

14. The support tray of claim 13, wherein the support tray further comprises a tab feature extending forward from the registration ledge, the tab feature being configured to limit side-to-side movement of a substrate supported by the support tray.

15. The support tray of claim 11, wherein the support tray comprises a pin extending upward from the support tray, the pin being configured to mate with a registration hole of a substrate supported by the support tray.

16. The support tray of claim 15, wherein the pin has a tapered profile near a distal end A method of supporting a substrate within a substrate container including a shell defining an opening and a door configured to selectively seal the opening; the method comprising:
placing the substrate on a cantilevered support tray; and
locating the support tray within the shell.

17. A method of supporting a substrate within a substrate container including a shell defining an opening and a door configured to selectively seal the opening; the method comprising:
placing the substrate on a cantilevered support tray; and
locating the support tray within the shell.

18. The method of claim 17, wherein locating the support tray within the shell includes coupling the support tray to at least one support post such that the support tray is cantilevered from the support post.

19. The method of claim 17, wherein the support tray includes a pin extending upward from the support tray, and placing the substrate on the support tray includes causing the pin to mate with a registration hole of the substrate.

20. An article comprising, a frame assembly for supporting a flexible substrate, the frame assembly having a peripheral frame defining an internal opening, and plurality of latches secured to the peripheral frame, wherein the plurality of latches selectively engages at least a portion of a flexible substrate to secure the flexible substrate to the frame assembly.

21. An article according to claim 20, wherein the frame assembly is placed on the cantilevered support tray of claim 1.

22. An article according to claim 20, wherein the frame assembly is placed in a front opening unified pod.

23. An article according to claim 20, further comprising a cantilevered spring integrally formed within the frame, wherein the spring is actuated by a cam lobe on the latch.
